(19) United States
(12) Patent Application Publication
(10) Pub. No.: US 2024/0105454 A1
(43) Pub. Date: Mar. 28, 2024

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Tung-Ying Lee, Hsinchu City (TW); Wei-Sheng Yun, Taipei City (TW); Yi-Tse HUNG, Hsinchu (TW); Shao-Ming YU, Hsinchu County (TW); Meng-Zhan Li, Changhua County (TW)

(73) Assignee: Taiwan Semiconductor Manufacturing Company, Ltd., Hsinchu (TW)

(21) Appl. No.: 18/177,144

(22) Filed: Mar. 2, 2023

Related U.S. Application Data
(60) Provisional application No. 63/409,216, filed on Sep. 23, 2022.

(51) Int. Cl. H01L 21/285; H01L 21/28; H01L 21/3105; H01L 29/51; H01L 29/786

(52) U.S. Cl. CPC H01L 21/285; H01L 21/28079; H01L 21/3105; H01L 29/517; H01L 29/78681

(57) ABSTRACT

A method for manufacturing a semiconductor device is described. The method includes the following steps. A low-dimensional material (LDM) layer is formed on a semiconductor substrate, wherein the LDM layer includes sublayers stacked upon one another. A plasma treatment is performed to the LDM layer to transform at least one sublayer into an oxide layer, wherein the plasma treatment is performed under a temperature equivalent to or lower than about 80 degrees Celsius. At least one electrode is disposed over the oxide layer.

### CROSS-REFERENCE TO RELATED APPLICATION

This application claims the priority benefit of U.S. provisional application Ser. No. 63/409,216, filed on Sep. 23, 2022. The entirety of the above-mentioned patent application is hereby incorporated by reference herein and made a part of this specification.

### BACKGROUND

Developments in shrinking sizes of semiconductor devices and electronic components make the integration of more devices and components into a given volume possible and lead to high integration density of various semiconductor devices and/or electronic components. In this regard, individual transistors, interconnects, and related structures have become increasingly smaller and there is an ongoing need to develop new materials, processes, and designs of semiconductor devices and interconnects to allow further progress.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 3 are schematic cross-sectional views of various stages in a manufacturing method of a semiconductor device in accordance with some embodiments of the disclosure.

FIG. 4 is a schematic cross-sectional view showing a semiconductor device in accordance with some embodiments of the disclosure.

FIG. 5 to FIG. 6 are schematic cross-sectional views of various stages in a manufacturing method of a semiconductor device in accordance with some embodiments of the disclosure.

FIG. 7 is a schematic cross-sectional view showing a semiconductor device in accordance with some embodiments of the disclosure.

FIG. 8 to FIG. 9 are schematic cross-sectional views of various stages in a manufacturing method of a semiconductor device in accordance with some embodiments of the disclosure.

FIG. 10 is a schematic cross-sectional view showing a semiconductor device in accordance with some embodiments of the disclosure.

FIG. 11 to FIG. 14 are schematic cross-sectional views of various stages in a manufacturing method of a semiconductor device in accordance with some embodiments of the disclosure.

FIG. 15 is a schematic cross-sectional view showing a semiconductor device in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first,” “second,” “third,” “fourth,” and the like, may be used herein for ease of description to describe similar or different element(s) or feature(s) as illustrated in the figures, and may be used interchangeably depending on the order of the presence or the contexts of the description.

A two-dimensional semiconductor (also known as a 2D semiconductor) is a type of natural semiconductor with thicknesses on the atomic scale. Transition metal dichalcogenides have been used in 2D devices. In accordance with some embodiments of the present disclosure, a semiconductor device may include a low-dimensional material (LDM) layer and electrodes disposed over the LDM layer, and electrical signals can be transmitted between the electrodes within the LDM layer. In some embodiments, the LDM layer includes sublayers stacked upon one another, wherein at least one sublayer (monolayer) is transformed into an oxide layer by performing a plasma treatment under a specific process temperature. The specific process temperature is, for example, equivalent to or lower than about 80 degrees Celsius. While the process temperature is decreased, it is easier to control the conversion rate of the LDM layer, through which the transformed portion of the LDM layer has a uniform thickness on the atomic monolayer scale. Therefore, the threshold voltage of the semiconductor device can be improved, which leads to better device performance.

It should be appreciated that the following embodiment(s) of the present disclosure provides applicable concepts that can be embodied in a wide variety of specific contexts. The specific embodiment(s) discussed herein is merely illustrative and is related to an integration structure containing more than one type of semiconductor devices, and is not intended to limit the scope of the present disclosure. Embodiments of the present disclosure describe the exemplary manufacturing process of integration structures formed with one or more semiconductor devices such as transistors and the integration structures fabricated there-from. Certain embodiments of the present disclosure are related to the structures including semiconductor transistors and other semiconductor devices. The substrates and/or wafers may include one or more types of integrated circuits or electronic components therein. The semiconductor device(s) may be formed on a bulk semiconductor substrate or a silicon/germanium-on-insulator substrate. The embodiments are intended to provide further explanations but are not used to limit the scope of the present disclosure. Throughout the various views and illustrative embodiments, like reference numbers are used to designate like elements. Although method embodiments may be discussed as being performed in a particular order, other method embodiments may be performed in any logical order.

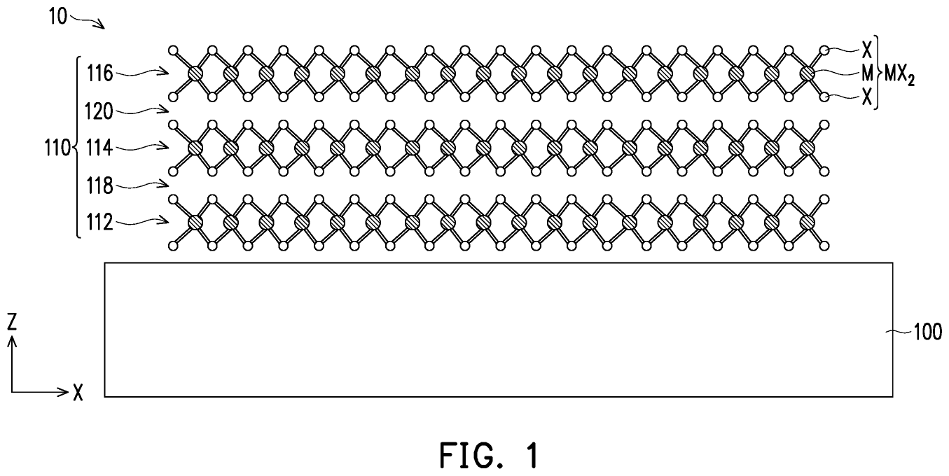

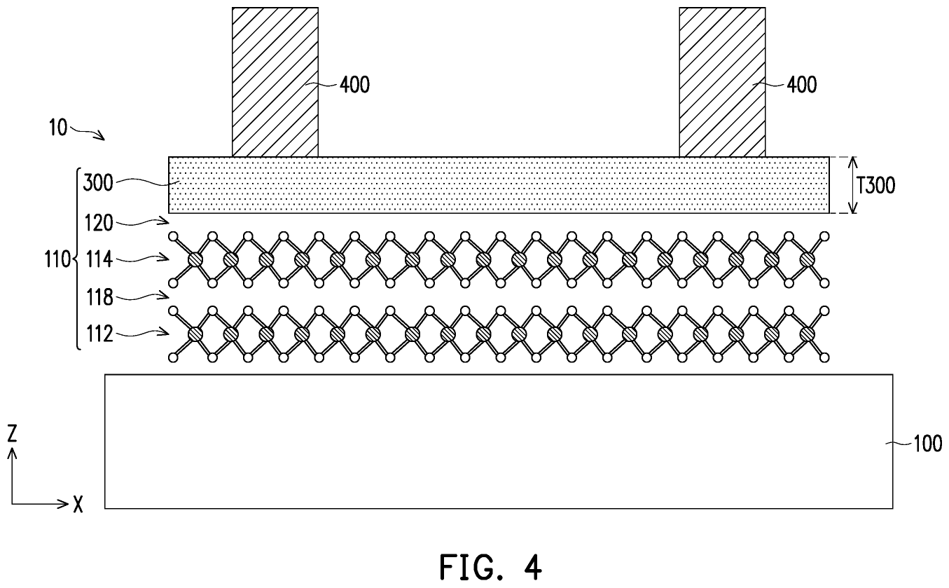

FIG. 1 to FIG. 3 are schematic cross-sectional views of various stages in a manufacturing method of a semiconductor device 10 in accordance with some embodiments of the disclosure. FIG. 4 is a schematic cross-sectional view showing the semiconductor device 10 in accordance with some embodiments of the disclosure.

Referring to FIG. 1, in some embodiments, a substrate 100 is provided. In some embodiments, the substrate 100 includes one or more active components such as transistors, diodes, optoelectronic devices and/or one or more passive components such as capacitors, inductors and resistors. In some embodiments, the substrate 100 includes a semiconductor substrate. In one embodiment, the substrate 100 comprises a crystalline silicon substrate or a doped semiconductor substrate (e.g., p-type semiconductor substrate or n-type semiconductor substrate). In certain embodiments, the substrate 100 comprises one or more doped regions or various types of doped regions, depending on design requirements. In some embodiments, the doped regions are doped with p-type and/or n-type dopants. For example, the p-type dopants are boron or BF₂ and the n-type dopants are phosphorus or arsenic. The doped regions may be configured for an n-type metal-oxide-semiconductor (NMOS) transistor or a p-type MOS (PMOS) transistor. In some alternative embodiments, the substrate 100 includes a semiconductor substrate made of other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide.

In some embodiments, a low-dimensional material (LDM) layer 110 is formed on a substrate 100. In some embodiments, the LDM layer includes sublayers stacked upon one another. In one embodiment, each of the sublayers is or includes an atomic monolayer and has a thickness on the atomic scale. As shown in FIG. 1, the LDM layer 110 includes, for example, a first LDM sublayer 112, a second LDM sublayer 114, and a third LDM sublayer 116 sequentially stacked on the substrate 100 from the bottom to the top. In some embodiments, the LDM sublayers 112, 114, and 116 respectively are monolayers respectively having a thickness in a range of about 5 angstroms to about 10 angstroms. In other embodiments, at least one of the LDM sublayers 112, 114, and 116 includes multiple monolayers in a stacked arrangement. In further embodiments, depending on the material, a van der Waals gap may be present between any two most adjacent LDM sublayers. As shown in FIG. 1, a van der Waals gap 118 is present between the LDM sublayers 112 and 114, and a van der Waals gap 120 is present between the LDM sublayers 114 and 116.

In some embodiments, a low-dimensional material of the LDM sublayers 112, 114, or 116 is or includes metal chalcogenide, such as metal dichalcogenide, excluding metal oxide. The metal dichalcogenide includes a metal M and chalcogen X and is represented by MX₂ in FIG. 1. In some embodiments, the metal dichalcogenide MX₂ is a transition metal dichalcogenide. The metal M is selected from the group consisting of W, Mo, and Pd. The chalcogen X is one or more selected from the group consisting of Se, S, and Te. In certain embodiments, the metal dichalcogenide MX₂ is selected from the group consisting of WSe₂, WS₂, WTe₂, MoSe₂, and PdSe₂. In other embodiments, materials of the LDM sublayers 112, 114, and 116 are different transition metal dichalcogenides. In some embodiments, processes to form the LDM sublayers 112, 114, and 116 on the substrate 100 include chemical vapor deposition (CVD), etc.

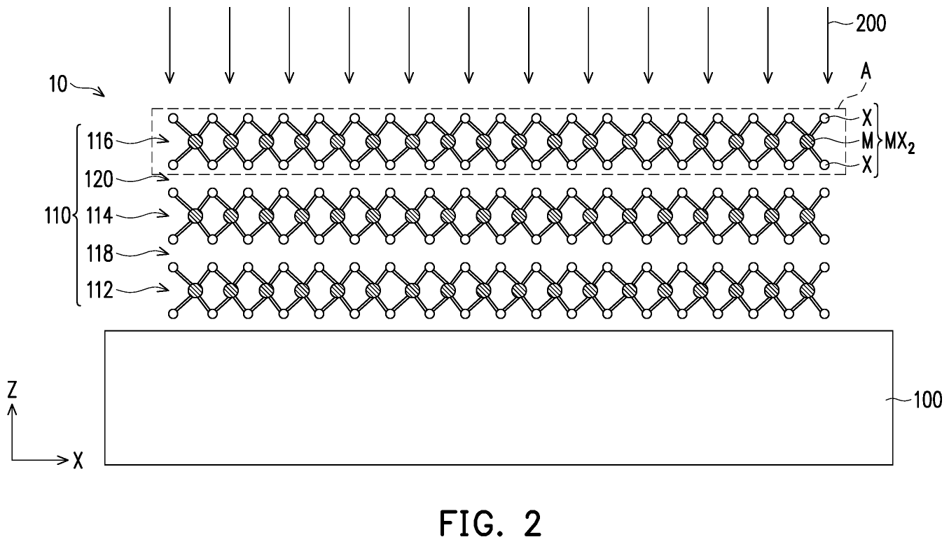

Referring to FIG. 2, in some embodiments, a plasma treatment 200 is performed to modified the LDM layer 110 under a specific process temperature. In other words, the semiconductor device 10 is kept in an environment, such as a chamber for performing the plasma treatment, under the specific process temperature during the plasma treatment 200. In some embodiments, the plasma treatment 200 is performed under a process temperature equivalent to or lower than about 80 degrees Celsius. In certain embodiments, the process temperature ranges from about −40 degrees Celsius to about 80 degrees Celsius or about −40 degrees Celsius to about 25 degrees Celsius. In further embodiments, the process temperature is less than room temperature. In one embodiment, the process temperature is within a range of about −40 degrees Celsius to about 0 degree Celsius. While the process temperature is decreased, it is easier to control the conversion rate of the LDM layer 110, through which the LDM layer 110 is transformed on the scale of atomic monolayer(s) (i.e. monolayer by monolayer). Therefore, the transformed portion of the LDM layer 110 has a uniform thickness on the atomic monolayer scale. Furthermore, performing the plasma treatment 200 under the above-mentioned low process temperature also prevents the devices (including the active components and/or the passive components) disposed below the LDM layer 110 from being damaged (e.g., thermal damage).

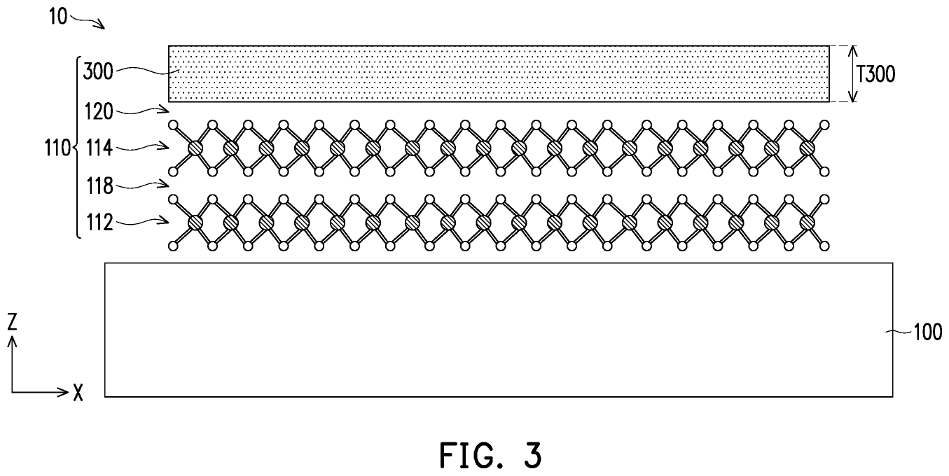

In some embodiments, the plasma treatment 200 includes performing an oxygen plasma treatment. Referring to FIG. 3, after performing the plasma treatment 200 (or the oxygen plasma treatment) to the LDM layer 110, at least one sublayer of the LDM layer 110 is transformed into an oxide layer. For instance, as shown in FIG. 2 and FIG. 3, the plasma treatment 200 is applied to the third LDM sublayer 116 (box A in FIG. 2), and the third LDM sublayer 116 is oxidized to form an oxide layer 300 in the semiconductor device 10. In certain embodiments, the third LDM sublayer 116 is wholly transformed into the oxide layer 300 through performing the plasma treatment 200. The mechanism of transforming the third LDM sublayer 116 into the oxide layer 300 includes, for example, that the chalcogens X of the metal dichalcogenide MX₂ of the third LDM sublayer 116 are removed and replaced with oxygen to form the oxide layer 300. Therefore, the third LDM sublayer 116 is transformed into the oxide layer 300 without changing the LDM sublayers 112 and 114. In such embodiments, the oxide layer 300 has a uniform thickness T300 larger than or substantially equal to a thickness of the third LDM sublayer 116. For example, the thickness T300 of the oxide layer 300 is in a range of about 6 angstroms to about 20 angstroms. In some embodiments, a material of the oxide layer 300 is or includes a metal oxide. In further embodiments, the metal oxide includes tungsten oxide, molybdenum oxide, or palladium oxide.

In some embodiments, the processing time of the process for forming the oxide layer 300 is less than 10 minutes. In other embodiments, the processing time of the process for forming the oxide layer 300 may be adjusted according to design requirements. In some embodiments, the plasma treatment 200 is applied at a power ranging from about 5 W to about 500 W. The number of the LDM sublayers that are oxidized by the plasma treatment 200 shown in FIG. 2 is merely for illustration purposes. In some alternative embodiments, more than one LDM sublayers may be oxidized, and the power of the plasma treatment 200 may be adjusted according to the number of the sublayers needed to be oxidized. For instance, as a higher power is applied for the plasma treatment 200, the plasma treatment is able to reach a larger depth into the LDM layer 110, thus more sublayers are oxidized (increasing the number of oxidized sublayers).

Referring to FIG. 4, in some embodiments, electrodes 400 are disposed over the oxide layer 300. Any numbers of electrodes 400 in the semiconductor device 10 may be used and are within the scope of the present disclosure. In some embodiments, the electrodes 400 are or include W, Pd, or other suitable metal. Up to here, the semiconductor device 10 in accordance with some embodiments of the present disclosure is obtained. In some embodiments, the electrodes 400 function as source and drain terminals of the transistor. In contrast to the semiconductor device without the oxide layer, the semiconductor device 10 with the oxide layer 300 has a lower initial leakage current. Further, a positive shift of the threshold voltage (Vth) is observed for the semiconductor device 10 with the oxide layer, in contrast to the semiconductor device without the oxide layer. In the illustrated embodiments, the described manufacturing processes and methods and the structures thereof are compatible with the current semiconductor manufacturing processes. In exemplary embodiments, the described methods and structures are formed during back-end-of-line (BEOL) processes.

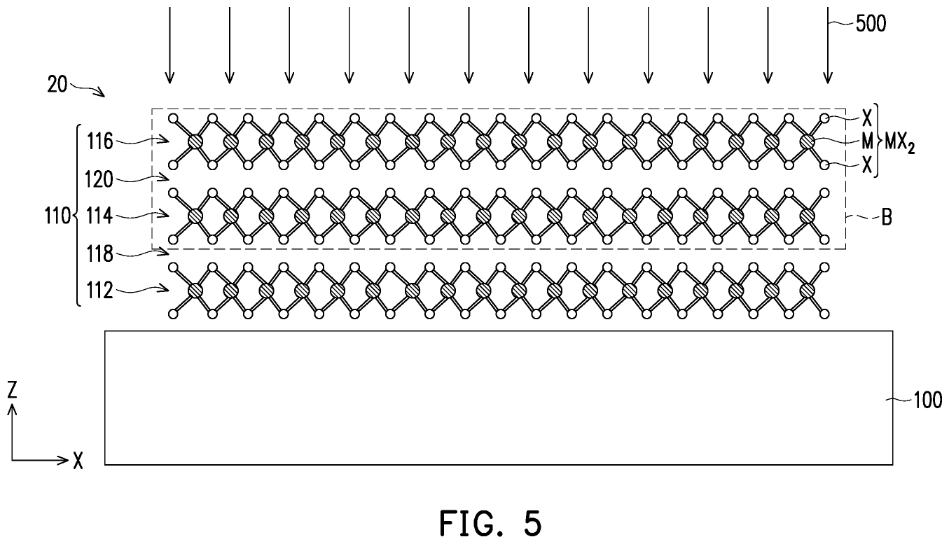

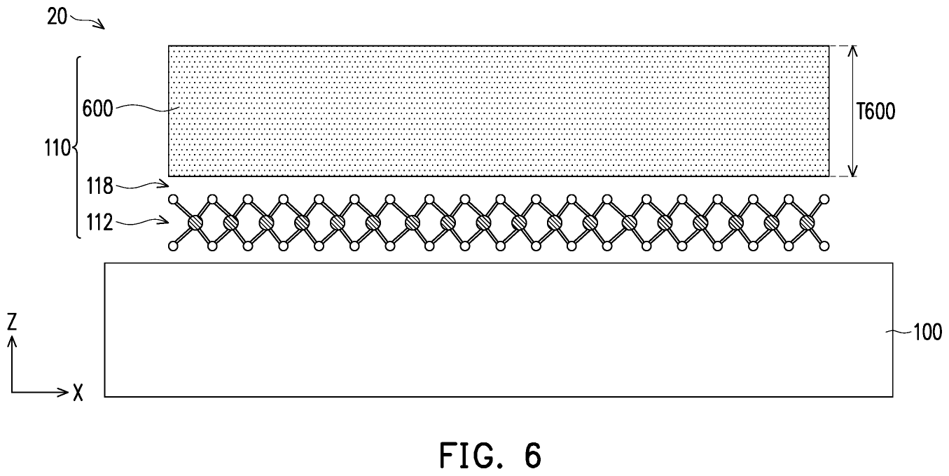

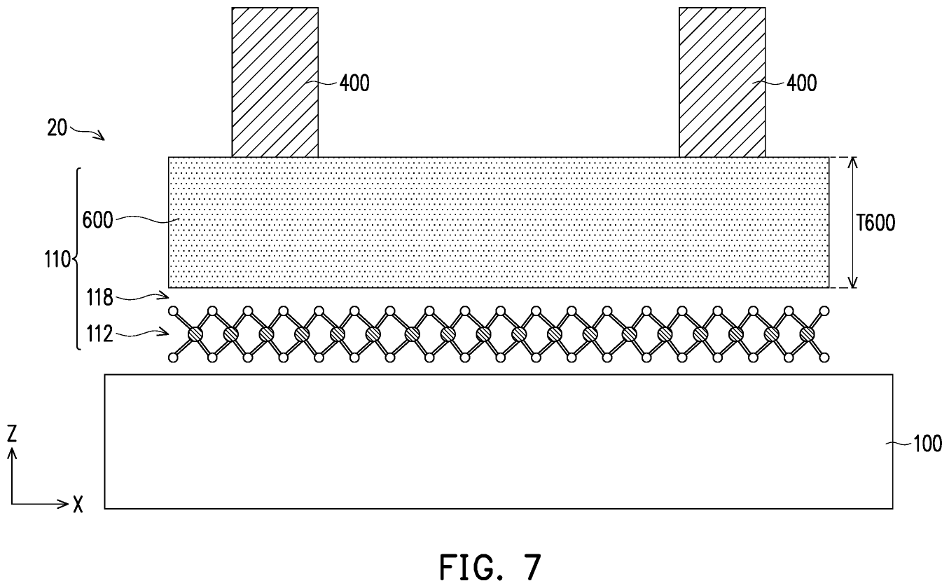

FIG. 5 to FIG. 6 are schematic cross-sectional views of various stages in a manufacturing method of a semiconductor device 20 in accordance with some embodiments of the disclosure. FIG. 7 is a schematic cross-sectional view showing the semiconductor device 20 in accordance with some embodiments of the disclosure.

Referring to FIG. 5, in some embodiments, a plasma treatment 500 is performed to modify the LDM layer 110 under a specific process temperature. Similar to the semiconductor device 10 in the previous embodiments, the semiconductor device 20 is kept in the environment under the specific process temperature during the plasma treatment 500. In some embodiments, the plasma treatment 500 is performed under a process temperature equivalent to or lower than about 80 degrees Celsius. In certain embodiments, the process temperature ranges from about −40 degrees Celsius to about 80 degrees Celsius, about −40 degrees Celsius to about 25 degrees Celsius, or about −40 degrees Celsius to about 0 degree Celsius.

In some embodiments, the plasma treatment 500 includes performing an oxygen plasma treatment. The plasma treatment 500 is applied with a power greater than that of the plasma treatment 200 in FIG. 2. Referring to FIG. 5 and FIG. 6, the plasma treatment 500 is applied to the third and the second LDM sublayers 116 and 114 (box B in FIG. 5), and the LDM sublayers 116 and 114 are oxidized to form an oxide layer 600 in the semiconductor device 20. In certain embodiments, the LDM sublayers 116 and 114 are wholly transformed into the oxide layer 600 through performing the plasma treatment 500. The mechanism of transforming the LDM sublayers 116 and 114 into the oxide layer 600 includes, for example, that the chalcogens X of the metal dichalcogenide MX₂ of the LDM sublayers 116 and 114 are removed and replaced with oxygen to form the oxide layer 600. Therefore, the LDM sublayers 116 and 114 are transformed into the oxide layer 600 without changing the first LDM sublayer 112. In such embodiments, the oxide layer 600 has a uniform thickness T600 larger than or substantially equal to a sum of thicknesses of the LDM sublayers 116 and 114. In certain embodiments, the thickness T600 of the oxide layer 600 shown in FIG. 6 and FIG. 7 is larger than the thickness T300 of the oxide layer 300 shown in FIG. 3 as multiple sublayers 114, 116 are transformed into the oxide layer 600 in FIG. 6 and FIG. 7. For example, the thickness T600 of the oxide layer 600 is in a range of about 12 angstroms to about 40 angstroms. As shown in FIG. 6, in some embodiments, as the two sublayers 114, 116 are transformed into the oxide layer 600, the van der Waals gap 120 no longer exists, but the van der Waals gap 118 remains present. In some embodiments, a material of the oxide layer 600 is or includes a metal oxide, such as tungsten oxide, molybdenum oxide, or palladium oxide.

The number of the LDM sublayers oxidized by the plasma treatment 500 shown in FIG. 5 is merely for illustration purposes. In some alternative embodiments, more than two LDM sublayers may be oxidized in accordance with actual design requirements. As the number of the LDM sublayers that need to be oxidized increases, a higher power and/or an increased processing time is required for the process to form the oxide layer. In some embodiments, the plasma treatment 500 is applied at a power ranging from about 5 W to about 500 W. The processing time of the process for forming the oxide layer 600 is less than 10 minutes.

Referring to FIG. 7, in some embodiments, electrodes 400 are disposed over the oxide layer 600. Any numbers of electrodes 400 in the semiconductor device 20 may be used and are within the scope of the present disclosure. Up to here, the semiconductor device 20 in accordance with some embodiments of the present disclosure is obtained. Similar to the semiconductor device 10 in the previous embodiments, the semiconductor device 20 substantially function as the transistor, and the electrodes 400 of the semiconductor device 20 function as source and drain terminals of the transistor. Moreover, a positive shift of Vth is observed for the semiconductor device 20, in contrast to that of the semiconductor device without the oxide layer. In addition, with of the thicker oxide layer, the threshold voltage may shift more (positive shift), resulting in better device performance. In some embodiments, the Vth shifting for the semiconductor device 20 is greater than that of the semiconductor device 10 toward the positive value. In exemplary embodiments, the described methods and structures are formed during back-end-of-line (BEOL) processes.

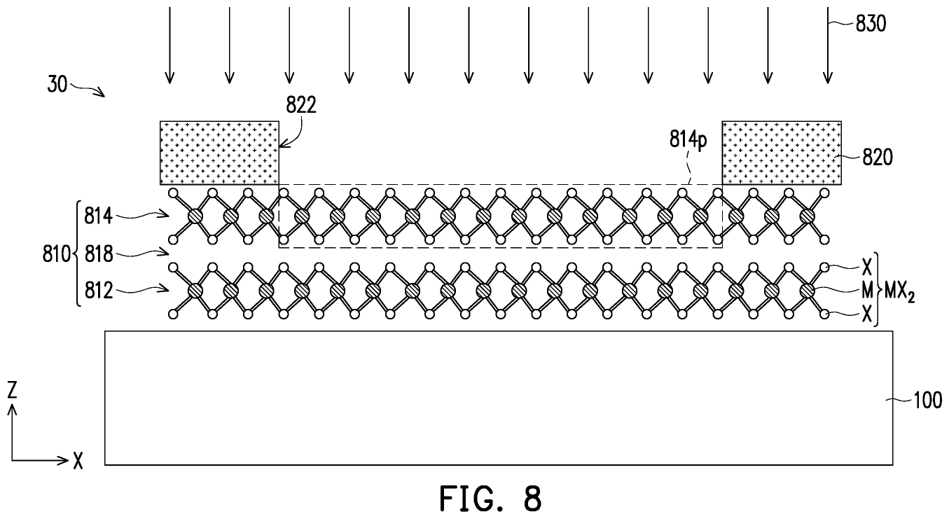

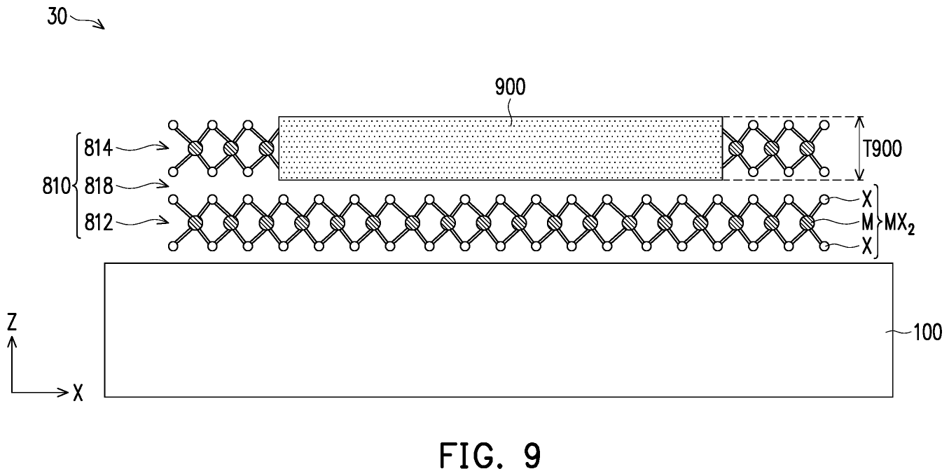

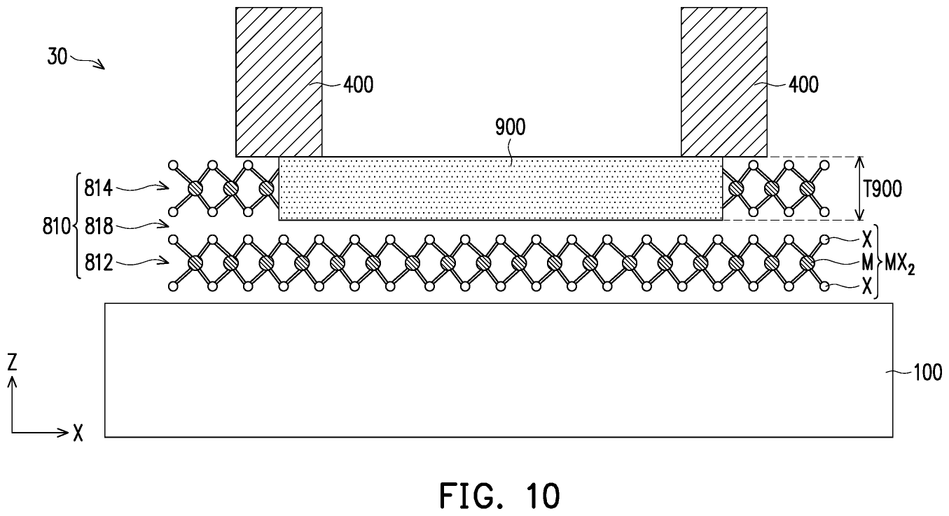

FIG. 8 to FIG. 9 are schematic cross-sectional views of various stages in a manufacturing method of a semiconductor device 30 in accordance with some embodiments of the disclosure. FIG. 10 is a schematic cross-sectional view showing the semiconductor device 30 in accordance with some embodiments of the disclosure.

Referring to FIG. 8, in some embodiments, a LDM layer 810 is formed on the substrate 100. In some embodiments, the LDM layer 810 is similar to the LDM layer 110 in the previous embodiments, and the LDM layer 810 includes a first LDM sublayer 812 and a second LDM sublayer 814 stacked on the first LDM sublayer 812. It is understood that the number of the LDM sublayers of the LDM layer 810 may be more than two, and the number of the LDM sublayers of the LDM layer 810 should not be limited by the exemplary embodiments or drawings of this disclosure. In some embodiments, the LDM sublayers 812 and 814 respectively are monolayers respectively having a thickness in a range of about 5 angstroms to about 10 angstroms. In other embodiments, at least one of the LDM sublayers 812 and 814 includes multiple monolayers in a stacked arrangement. In further embodiments, as shown in FIG. 8, a van der Waals gap 818 is present between the LDM sublayers 812 and 814. In some embodiments, a low-dimensional material of the LDM sublayer 812 or 814 is or includes the metal dichalcogenide MX₂, excluding metal oxide. In certain embodiments, the metal dichalcogenide MX₂ is selected from the group consisting of WSe₂, WS₂, WTe₂, MoSe₂, and PdSe₂. In other embodiments, materials of the LDM sublayers 812 and 814 are different transition metal dichalcogenides. In some embodiments, processes to form the LDM sublayers 812 and 814 on the substrate 100 include CVD, etc.

Subsequently, as shown in FIG. 8, a patterned buffer layer 820 is formed over the LDM layer 810 to expose a portion of the LDM layer 810. In some embodiments, the buffer layer 820 is a photoresist or an insulating layer, such as an oxide layer or a nitride layer. In one embodiment, the oxide layer is a silicon oxide (such as SiO₂) or silicon oxynitride (such as SiON). In one embodiment, the nitride layer is a silicon nitride, such as SiN. In some embodiments, the buffer layer 820 is formed by a photoresist deposition operation, CVD, or physical vapor deposition (PVD) operation.

In some embodiments, the buffer layer 820 is patterned to form an opening 822, wherein the opening 822 exposes a portion of the LDM layer 810. When the buffer layer 820 is a photoresist layer, the photoresist layer is patterned by photolithographic techniques, including selectively exposing the photoresist layer to actinic radiation and developing the selectively exposed photoresist layer. When the buffer layer 820 is an insulating layer, a photoresist layer is formed over the buffer layer and photolithographic and etching operations are performed to form the opening 822 in the buffer layer 820, followed by removing the photoresist layer by a suitable photoresist stripping or ashing operation in some embodiments.

As shown in FIG. 8, then a plasma treatment 830 is performed to the exposed portion of the LDM layer 810. In some embodiments, the plasma treatment 830 is applied to a portion 814p of the second LDM sublayer 814 (e.g., the box shown in FIG. 8). In some embodiments, the plasma treatment 830 is performed under the specific process temperature previously discussed herein. The processing time of the process for forming the oxidized portion 900 is about or less than 10 minutes. The plasma treatment 830 is applied at a power ranging from about 5 W to about 500 W.

In some embodiments, the plasma treatment 830 includes performing an oxygen plasma treatment. Referring to FIG. 9, as previously discussed, the chalcogens X of the metal dichalcogenide MX₂ of the second LDM sublayer 814 are removed and replaced with oxygen to form an oxidized portion 900 of the second LDM sublayer 814. In such embodiments, the second LDM sublayer 814 is partially transformed into the oxidized portion 900 without changing the first LDM sublayer 812 through performing the plasma treatment 830. By performing the plasma treatment with the buffer layer under the specific temperature, not only the conversion rate can be easily controlled to transform the LDM layer 810 monolayer by monolayer, but also the oxidized portion 900 can be precisely corresponded to the opening 822 of the buffer layer 820, which means the oxidized portion 900 of the LDM layer 810 can be precisely patterned into the desired pattern at a specific location/position. In some embodiments, the oxidized portion 900 has a uniform thickness T900 larger than or substantially equal to a thickness of the second LDM sublayer 814. For example, the thickness T900 of the oxidized portion 900 is in a range of about 6 angstroms to about 20 angstroms. In some embodiments, a material of the oxidized portion 900 is or includes a metal oxide, such as tungsten oxide, molybdenum oxide, or palladium oxide.

Subsequently, as shown in FIG. 9, the buffer layer 820 is removed. In some embodiments, the buffer layer 820 is removed by suitable photolithographic or etching operations, such as a lift-off operation by wet etching, however the disclosure is not limited thereto.

Referring to FIG. 10, electrodes 400 are disposed over the oxidized portion 900 of the LDM layer 810. Any numbers of electrodes 400 in the semiconductor device 30 may be used and are within the scope of the present disclosure. Up to here, the semiconductor device 30 in accordance with some embodiments of the present disclosure is obtained. In some embodiments, the semiconductor device 30 substantially function as the transistor, and the electrodes 400 of the semiconductor device 30 function as source and drain terminals of the transistor. Moreover, a positive shift of Vth is observed for the semiconductor device 30, in contrast to that of the semiconductor device without the oxide layer. In exemplary embodiments, the described methods and structures are formed during back-end-of-line (BEOL) processes.

In some embodiments, as shown in FIG. 10, two electrodes 400 are disposed beside opposite sides of the oxidized portion 900. That is, when viewed from the top, the oxidized portion 900 of the LDM layer 810 is disposed between the two electrodes 400. In some embodiments, as shown in FIG. 10, the two electrodes 400 are in direct contact with and partially overlapped with the oxidized portion 900 of the LDM layer 810. In other embodiments, the locations of the two electrodes 400 are vertically overlapped (partially or fully) with the location of the oxidized portion 900 of the LDM layer 810. In some alternative embodiments, the two electrodes 400 are in direct contact with the oxidized portion 900 of the LDM layer 810 and fall within the span of the oxidized portion 900.

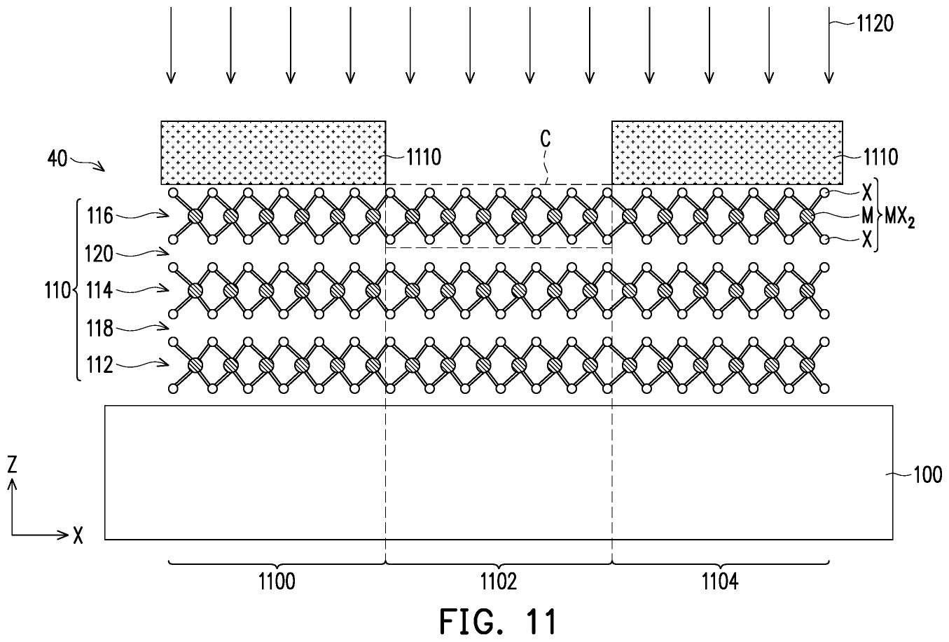

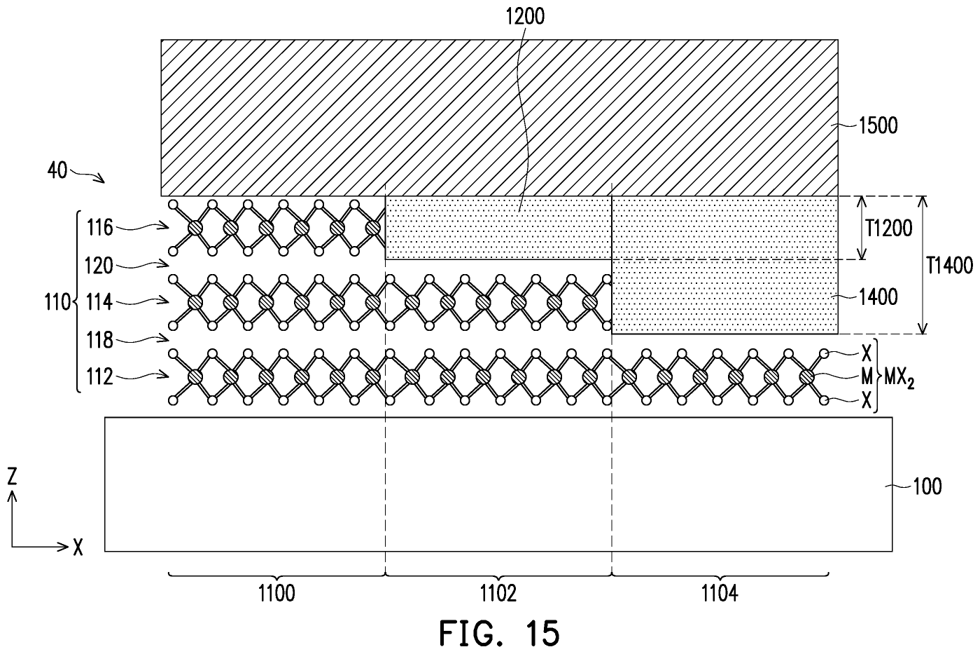

FIG. 11 to FIG. 14 are schematic cross-sectional views of various stages in a manufacturing method of a semiconductor device 40 in accordance with some embodiments of the disclosure. FIG. 15 is a schematic cross-sectional view showing the semiconductor device 40 in accordance with some embodiments of the disclosure.

Referring to FIG. 11, in some embodiments, the LDM layer 110 has a first portion 1100, a second portion 1102, and a third portion 1104, wherein the second portion 1102 is disposed between the portions 1100 and 1104. As shown in FIG. 11, a first buffer layer 1110 is formed over the portions 1100 and 1104 of the LDM layer 110. In other words, the first buffer layer 1110 exposes the second portion 1102 of the LDM layer 110. In some embodiments, the first buffer layer 1110 is a photoresist or an insulating layer, such as an oxide layer or a nitride layer. In one embodiment, the oxide layer is a silicon oxide (such as SiO₂) or silicon oxynitride (such as SiON). In one embodiment, the nitride layer is a silicon nitride, such as SiN. In some embodiments, the first buffer layer 1110 is formed by a photoresist deposition operation, CVD, or PVD operation.

Subsequently, as shown in FIG. 11, a first plasma treatment 1120 is applied to the exposed third LDM sublayer 116 in the second portion 1102 of the LDM layer 110 (box C in FIG. 11). In some embodiments, the first plasma treatment 1120 is performed under the specific process temperature previously discussed herein. The first plasma treatment 1120 is applied at a power ranging from about 5 W to about 500 W.

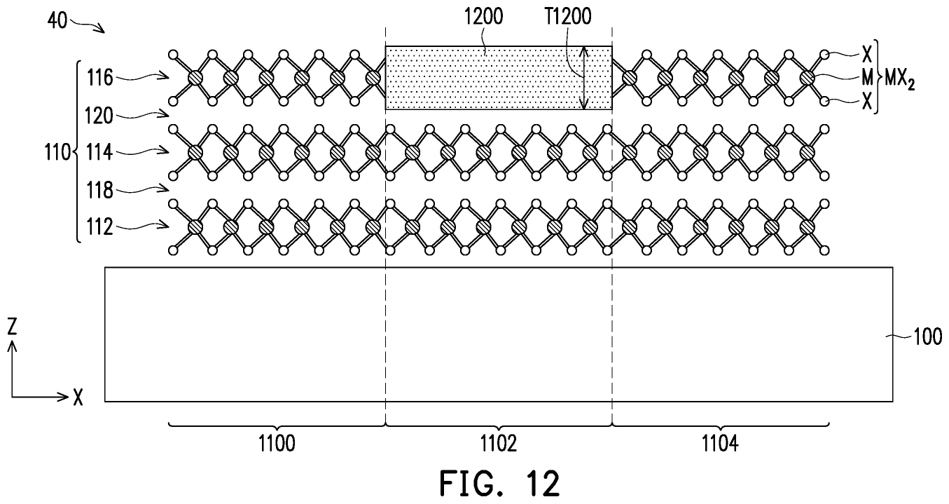

Referring to FIG. 12, a first oxidized portion 1200 is then formed in the third LDM sublayer 116. In some embodiments, the processing time of the process for forming the first oxidized portion 1200 is about or less than 10 minutes. In such embodiments, the third LDM sublayer 116 is partially transformed into the first oxidized portion 1200 without changing the LDM sublayers 112 and 114 through performing the first plasma treatment 1120. In some embodiments, the first oxidized portion 1200 has a uniform thickness T1200 larger than or substantially equal to the thickness of the third LDM sublayer 116. Thereafter, as shown in FIG. 12, the first buffer layer 1110 is removed by suitable photolithographic or etching operations.

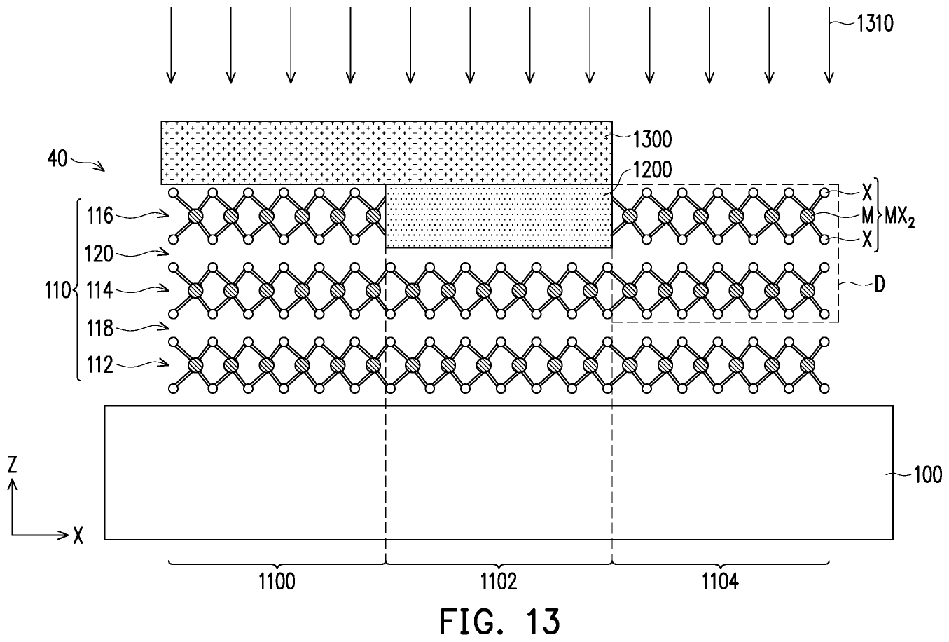

Referring to FIG. 13, in some embodiments, a second buffer layer 1300 is formed over the portions 1100 and 1102 of the LDM layer 110. In other words, the second buffer layer 1300 exposes the third portion 1104 of the LDM layer 110. In one embodiment, the second buffer layer 1300 covers the first oxidized portion 1200 of the LDM layer 110. In some embodiments, similar to the first buffer layer 1110, the second buffer layer 1300 is a photoresist or an insulating layer, such as the oxide layer or the nitride layer. In some embodiments, the second buffer layer 1300 is formed by a photoresist deposition operation, CVD, or PVD operation.

Subsequently, as shown in FIG. 13, a second plasma treatment 1310 is applied to the exposed LDM sublayers 116 and 114 in the third portion 1104 of the LDM layer 110 (box D in FIG. 13). In some embodiments, the second plasma treatment 1310 is performed under the specific process temperature previously discussed herein. The second plasma treatment 1310 is applied at a power ranging from about 5 W to about 500 W. In one embodiment, the second plasma treatment 1310 is applied with a power greater than that of the first plasma treatment 1120 in FIG. 11.

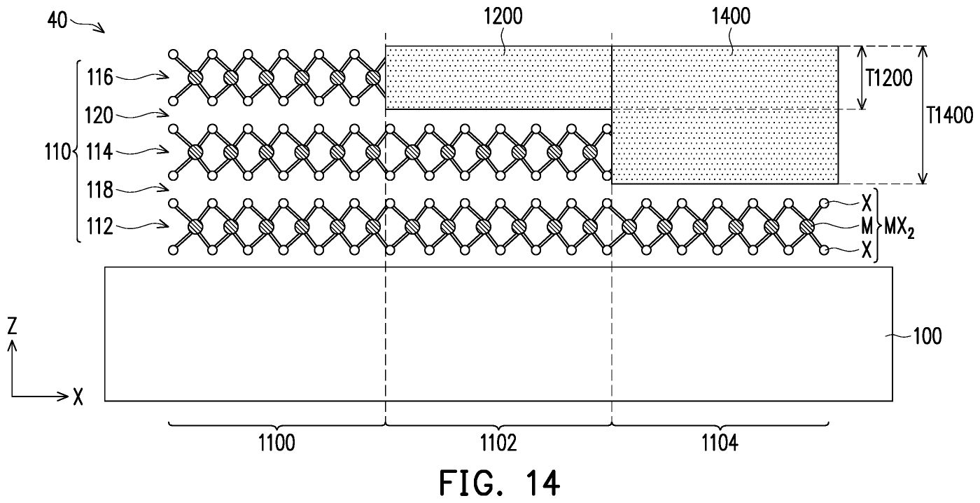

Referring to FIG. 14, a second oxidized portion 1400 is then formed in the LDM sublayers 114 and 116. In some embodiments, the processing time of the process for forming the second oxidized portion 1400 is about or less than 10 minutes. As shown in FIG. 14, in some embodiments, the van der Waals gap 120 in the third portion 1104 of the LDM layer 110 no longer exists. In such embodiment, the LDM sublayers 114 and 116 are partially transformed into the second oxidized portion 1400 without changing the LDM sublayer 112 through performing the second plasma treatment 1310. In some embodiments, the second oxidized portion 1400 has a uniform thickness T1400 larger than or substantially equal to a sum of the thicknesses of the LDM sublayers 116 and 114. By performing multiple plasma treatments with buffer layers of various patterns under the specific temperature(s), the formation of the oxide layer(s) or oxidized portion(s) can be individually tuned so that the thicknesses of the oxide layer(s) and the thickness and locations of the oxidized portions in the LDM layer can be adjusted according to product requirements. As shown in FIG. 14, in the LDM layer 110 of the semiconductor device 30, the first portion 1100 is not oxidized, the second portion 1102 has the first oxidized portion 1200 having the thickness substantially equal to one monolayer, and the third portion 1104 has the second oxidized portion 1400 having the thickness substantially equal to that of two monolayers. Thereafter, as shown in FIG. 14, the second buffer layer 1300 is removed by suitable photolithographic or etching operations.

Referring to FIG. 15, in some embodiments, an electrode 1500 is formed over the portions 1100, 1102, and 1104 of the LDM layer 110. In some alternative embodiments, the electrode 1500 is formed over at least one of the portions 1100, 1102, and 1104 of the LDM layer 110. Up to here, the semiconductor device 40 in accordance with some embodiments of the present disclosure is obtained. As shown in FIG. 15, the semiconductor device 40 comprises the LDM layer 110 disposed on the substrate 100 and the electrode 1500 disposed over the LDM layer 110. In some embodiments, the LDM layer 110 includes the first oxidized portion 1200 and the second oxidized portion 1400. In certain embodiments, the second oxidized portion 1400 of the LDM layer 110 has a thickness T1400 larger than the thickness T1200 of the first oxidized portion 1200 of the LDM layer 110. For example, the thickness T1200 of the first oxidized portion 1200 is in a range of about 6 angstroms to about 20 angstroms. The thickness T1400 of the second oxidized portion 1400 is in a range of about 12 angstroms to about 40 angstroms. In some embodiments, materials of the oxidized portions 1200 and 1400 are or include a metal oxide, such as tungsten oxide, molybdenum oxide, or palladium oxide. In some embodiments, the semiconductor device 40 substantially function as the transistor, and the electrode 1500 of the semiconductor device 40 function as the source or drain terminal of the transistor. Moreover, a positive shift of Vth is observed for the semiconductor device 40, in contrast to that of the semiconductor device without the oxide layer. In exemplary embodiments, the described methods and structures are formed during back-end-of-line (BEOL) processes.

A semiconductor device and a manufacturing method thereof are provided. The embodiments of the present disclosure have some advantageous features. In accordance with some embodiments of the present disclosure, a semiconductor device may include a low-dimensional material (LDM) layer and electrodes disposed over the LDM layer, and electrical signals can be transmitted between the electrodes within the LDM layer. In some embodiments, the LDM layer includes sublayers stacked upon one another, wherein at least one sublayer (monolayer) is transformed into an oxide layer by performing a plasma treatment under a specific process temperature. The specific process temperature is, for example, equivalent to or lower than about 80 degrees Celsius. While the process temperature is decreased, it is easier to control the conversion rate of the LDM layer, through which the transformed portion of the LDM layer has a uniform thickness on the atomic monolayer scale. Therefore, the threshold voltage of the semiconductor device can be improved, which leads to better device performance.

In accordance with some embodiments of the present disclosure, a method for manufacturing a semiconductor device is described. The method includes the following steps. A low-dimensional material (LDM) layer is formed on a semiconductor substrate, wherein the LDM layer includes sublayers stacked upon one another. A plasma treatment is performed to the LDM layer to transform at least one sublayer into an oxide layer, wherein the plasma treatment is performed under a temperature equivalent to or lower than about 80 degrees Celsius. At least one electrode is disposed over the oxide layer.

In accordance with some embodiments of the present disclosure, a method for manufacturing a semiconductor device is described. The method includes the following steps. A first low-dimensional material (LDM) layer and a second LDM layer are formed sequentially on a semiconductor substrate. A plasma treatment is performed to transform the second LDM layer into an oxide layer without changing the first LDM layer. Electrodes are disposed over the oxide layer. The plasma treatment is performed under a temperature equivalent to or lower than about 80 degrees Celsius.

In accordance with some embodiments of the present disclosure, a semiconductor device comprises a low-dimensional material (LDM) layer and electrodes. The LDM layer is disposed on a semiconductor substrate, wherein the LDM layer includes a first oxidized portion and a second oxidized portion. The electrodes are disposed over the LDM layer. The second oxidized portion of the LDM layer has a thickness larger than that of the first oxidized portion of the LDM layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a low-dimensional material (LDM) layer on a semiconductor substrate, wherein the LDM layer includes sublayers stacked upon one another;
performing a plasma treatment to the LDM layer to transform at least one sublayer into an oxide layer, wherein the plasma treatment is performed under a temperature equivalent to or lower than about 80 degrees Celsius; and
disposing at least one electrode over the oxide layer.

2. The method according to claim 1, wherein performing a plasma treatment includes performing an oxygen plasma treatment, and the temperature ranges from about −40 degrees Celsius to about 80 degrees Celsius.

3. The method according to claim 1, wherein performing a plasma treatment includes performing an oxygen plasma treatment, and the temperature ranges from about −40 degrees Celsius to about 25 degrees Celsius.

4. The method according to claim 1, wherein performing a plasma treatment to the LDM layer to transform at least one sublayer into an oxide layer includes:
forming a buffer layer over the LDM layer to expose a portion of the LDM layer; and
performing the plasma treatment to the exposed portion of the LDM layer to transform the at least one sublayer in the exposed portion to form an oxidized portion of the at least one sublayer.

5. The method according to claim 4, wherein disposing at least one electrode over the oxide layer includes disposing a first electrode and a second electrode over the LDM layer and beside opposite sides of the oxidized portion, so that the oxidized portion is disposed between the first and second electrodes.

6. The method according to claim 1, wherein the at least one sublayer is wholly transformed into the oxide layer through performing the plasma treatment.

7. The method according to claim 1, wherein a low-dimensional material of the LDM layer includes WSe₂, WS₂, WTe₂, MoSe₂, or PdSe₂.

8. The method according to claim 7, wherein a material of the oxide layer includes tungsten oxide, molybdenum oxide, or palladium oxide.

9. A method for manufacturing a semiconductor device, comprising:
forming a first low-dimensional material (LDM) layer and a second LDM layer sequentially on a semiconductor substrate;
performing a plasma treatment to transform the second LDM layer into an oxide layer without changing the first LDM layer; and
disposing electrodes over the oxide layer,
wherein the plasma treatment is performed under a temperature equivalent to or lower than about 80 degrees Celsius.

10. The method according to claim 9, wherein performing a plasma treatment includes performing an oxygen plasma treatment, and the temperature ranges from about −40 degrees Celsius to about 80 degrees Celsius.

11. The method according to claim 9, wherein performing a plasma treatment includes performing an oxygen plasma treatment, and the temperature ranges from about −40 degrees Celsius to about 25 degrees Celsius.

12. The method according to claim 9, wherein performing a plasma treatment to transform the second LDM layer into an oxide layer includes:
forming a buffer layer over the second LDM layer to expose a portion of the second LDM layer; and
performing the plasma treatment to transform the second LDM layer in the exposed portion to form an oxidized portion of the second LDM layer.

13. The method according to claim 12, wherein disposing electrodes over the oxide layer includes disposing a first electrode and a second electrode over the second LDM layer and beside opposite sides of the oxidized portion, so that the oxidized portion is disposed between the first and second electrodes.

14. The method according to claim 9, wherein the second LDM layer includes a first sublayer and a second sublayer stacked on the first sublayer, and performing a plasma treatment to transform the second LDM layer into an oxide layer includes:
forming a first buffer layer over the second LDM layer to expose a first portion of the second LDM layer;
performing a first plasma treatment to the exposed first portion of the second LDM layer to transform the second sublayer in the exposed first portion to form a first oxidized portion in the second LDM layer;
forming a second buffer layer over the second LDM layer to expose a second portion of the second LDM layer, wherein the second portion is different from the first portion; and
performing a second plasma treatment to the exposed second portion of the second LDM layer to transform the first and second sublayers in the exposed second portion to form a second oxidized portion in the second LDM layer,
wherein the first and second plasma treatments are performed under a temperature equivalent to or lower than about 80 degrees Celsius,
wherein the second oxidized portion of the second LDM layer has a thickness larger than that of the first oxidized portion of the second LDM layer.

15. The method according to claim 9, wherein a low-dimensional material of the second LDM layer includes WSe₂, WS₂, WTe₂, MoSe₂, or PdSe₂.

16. The method according to claim 15, wherein a material of the oxide layer includes tungsten oxide, molybdenum oxide, or palladium oxide.

17. A semiconductor device, comprising:
a low-dimensional material (LDM) layer disposed on a semiconductor substrate, wherein the LDM layer includes a first oxidized portion and a second oxidized portion; and
electrodes disposed over the LDM layer,
wherein the second oxidized portion of the LDM layer has a thickness larger than that of the first oxidized portion of the LDM layer.

18. The semiconductor device according to claim 17, wherein the electrodes include a first electrode and a second electrode, and the first or the second oxidized portion is disposed between the first and second electrodes.

19. The semiconductor device according to claim 17, wherein a low-dimensional material of the LDM layer includes WSe₂, WS₂, WTe₂, MoSe₂, or PdSe₂.

20. The semiconductor device according to claim 19, wherein a material of the first or the second oxidized portion includes tungsten oxide, molybdenum oxide, or palladium oxide.
